(19) United States
(12) Patent Application Publication
(10) Pub. No.: US 2009/0166765 A1
(43) Pub. Date: Jul. 2, 2009

(54) MOS TRANSISTOR AND METHOD FOR MANUFACTURING THE TRANSISTOR

(76) Inventor: Mun-Young Lee, Gyeyang-gu (KR)

Correspondence Address: SHERR & VAUGHN, PLLC, 620 HERNDON PARKWAY, SUITE 200, HERNDON, VA, 20170, US

(21) Appl. No.: 12/344,548

(22) Filed: Dec. 28, 2008

(30) Foreign Application Priority Data
Dec. 31, 2007 (KR) 10-2007-0141448

(51) Int. Cl. H01L 29/78; H01L 21/425

(52) U.S. Cl. 257/409; 438/514; 257/E29.256; 257/E21.473

(57) ABSTRACT

A MOS transistor and a method for manufacturing the transistor that may include forming a gate pattern on and/or over an active area of a semiconductor substrate defined as the active area and a field area, and silicide blocking films at each side of the gate pattern and partially over the uppermost surface of the gate pattern the silicide blocking films including first and second silicide blocking film portions formed spaced apart and extending in parallel to each other, and third and fourth silicide blocking film portions connected to the first and second silicide blocking film portions and formed spaced apart and extending in parallel to each other and perpendicular to the first and second silicide blocking film portions. With such a structural design, a high voltage transistor and middle voltage transistor having a reduced pitch size may be formed, thereby reducing the overall chip size.

The present application claims priority under 35 U.S.C. 119 to Korean Patent Application No. 10-2007-0141448 (filed on Dec. 31, 2007), which is hereby incorporated by reference in its entirety.

### BACKGROUND

FIG. 1A illustrates a plan view of a related art DE-NMOS transistor, and FIG. 1B illustrates a cross-sectional view taken along lines I-I′ of FIG. 1A. Referring to FIGS. 1A and 1B, N+ junctions 16A and 16B may be extended from gate 16 for high voltage devices in well 10 of a semiconductor substrate. Gate insulating film 14 may be formed at a lower portion of gate 16. Gate 16 may be formed on and/or over an active area defined between device isolation films 12A and 12B. Spacers 20 may be formed on and/or over sides of gate 16 and gate insulating film 14. Silicide layer 24 may be formed on and/or over upper portions of N+ junctions 16A and 16B and gate 16. Contacts 26A and 26B may be formed on and/or over silicide layer 24.

However, N+ junctions 18A and 18B within a drift junction may extend from gate 16. In such a situation, a pitch of a transistor that may have the above structure may increase. To secure high voltage drift junction breakdown voltage, Silicide Blocking (SAB) layers SAB 22A and 22B may be formed on and/or over drift areas 16A and 16B from gate 16 to N+ junctions 18A and 18B. Such a SAB pattern may be patterned only when a predetermined dimensional or more is secured for a distance from gate 16 to junctions 18A and 18B. If a width pitch a1 of a SAB pattern in the drift areas 16A and 16B is defined below critical dimension (CD), it may be difficult to secure the same pattern as an actual layout due to insufficient photo margin. This may result in a collapsed pattern issue when an etching process or a photo process using a minimum CD is performed. The collapsed pattern issue may be a phenomenon that for a small sized pattern, surfaces in contact with sub material may be insufficient or the CD pattern may be too small. This may cause the pattern to collapse.

FIG. 2 illustrates a plan view of a related art Medium voltage (MV) MOS transistor. The MV transistor may have an operation voltage corresponding to about ½ of a High Voltage (HV) transistor. Since a distance between contact 46 and gate 44 may be small, N+ ion implantation may be performed on and/or over active area 42 through a self alignment process. This may form N+ junction 48. A self alignment process may mean that N+ ions may be implanted to an entire active area of a transistor irrespective of gate 44 rather than N+ junctions 18A and 18B that may be formed with a distance from gate 16 as in a related art HV transistor. To form silicide on and/or over active area 42 on and/or over which contact 46 may be formed, a predetermined dimension may be obtained before reaching gate 44 from contact 46. To minimize increase of gate resistance, gate 44 and silicide blocking films may overlap with each other below a predetermined distance.

In a transistor structure formed through a self alignment process, silicide may be formed on and/or over all junction areas by patterning. Accordingly, a punch through relating to breakdown voltage, which may be an important property of a transistor, may be weak in junctions between high concentration source and drain due to a high electric field of the area on and/or over which the silicide film may be formed and to which high concentration ion is implanted. Therefore, to prevent this, CD of gate 44, that is, ‘e’, may increase. A width between gate 44 and contact 46 may thereby be narrow, which may cause a problem that a silicide blocking film may not be formed between contact 46 and gate 44.

### SUMMARY

Embodiment relate to a semiconductor device, and to a Metal-Oxide semiconductor (MOS) transistor, such as Drain Extended (DE) High Voltage (HV) or Middle Voltage (MV), that may be implemented as a semiconductor device, and a method for manufacturing the same.

Embodiments relate to a MOS transistor which may minimize a size of a pattern of a silicide blocking film, which may block silicide from forming between a gate pattern and contacts irrespective of a type of transistor, and a method for manufacturing the same.

Embodiments relate to a method for manufacturing a MOS transistor that may include at least one of the following: forming a gate pattern on and/or over an active area of a semiconductor substrate defined as the active area and a field area; and then extending vertically silicide blocking films horizontally adjacent to each other having the gate pattern therebetween to connect them to each other.

Embodiments relate to a MOS transistor that may include at least one of the following: a gate pattern formed on and/or over an active area of a semiconductor substrate defined as the active area and a field area; and then silicide blocking films horizontally adjacent to each other having the gate pattern therebetween and vertically extending to be connected to each other.

Embodiments relate to a method that may include at least one of the following: providing a semiconductor substrate having an active area and a field area; and then forming a gate pattern over the active area of the semiconductor substrate; and then forming silicide blocking films at each side of the gate pattern and partially over the uppermost surface of the gate pattern. In accordance with embodiments, the silicide blocking films include first and second silicide blocking film portions formed spaced apart and extending in parallel to each other, and third and fourth silicide blocking film portions connected to the first and second silicide blocking film portions and formed spaced apart and extending in parallel to each other and perpendicular to the first and second silicide blocking film portions

Embodiments relate to a device that may include at least one of the following: a semiconductor substrate including an active area and a field area; a gate pattern formed over the active area of the semiconductor substrate; and silicide blocking films at each side of the gate pattern and partially over the uppermost surface of the gate pattern. In accordance with embodiments, the silicide blocking films include first and second silicide blocking film portions formed spaced apart and extending in parallel to each other, and third and fourth silicide blocking film portions connected to the first and second silicide blocking film portions and formed spaced apart and extending in parallel to each other and perpendicular to the first and second silicide blocking film portions

### DRAWINGS

FIG. 1A is a plan view illustrating a related art DE-NMOS transistor.

FIG. 1B is a cross-sectional view taken along lines I-I′ of FIG. 1A.

FIG. 2 is a plan view illustrating a related art Medium voltage (MV) MOS transistor.

Example FIGS. 3 to 5 illustrate a MOS transistor and a method for manufacturing a MOS transistor, according to embodiments.

### DESCRIPTION

Example FIG. 3 illustrates a plan view of a MOS transistor according to embodiments. Referring to example FIG. 3, a semiconductor substrate may be defined as a field area and active area 62, and well 60 may be formed in the semiconductor substrate. Gate pattern 67, which may be formed on and/or over active area 62 in well 60, may include a poly silicon gate and a gate insulating film. In example FIG. 3, gate pattern 67 may intersect with active area 62. Drift areas 64A and 64B may cover source and drain areas at both sides of gate pattern 67. The source and drain areas may refer to the areas in active area 62 at both sides of gate pattern 67 on and/or over which source and drain may be formed.

According to embodiments, high concentration ion areas 66A and 66B may be formed in drift areas 64A and 64B, and may be spaced apart from gate pattern 67. Silicide blocking film 70 may be formed on and/or over upper portions of drift areas 64A and 64B, between gate pattern 67 and high concentration ion areas 66A and 66B. Silicide blocking films 72 and 74 may be horizontally adjacent to each other and may have gate pattern 67 therebetween. Silicide blocking films 72 and 74 may vertically extend and may be connected to silicide blocking films 76 and 78. Silicide blocking films 72 and 74 and silicide blocking films 76 and 78 may be connected to each other in the field area. A silicide film may be formed on and/or over areas of upper areas of gate pattern 67, and high concentration ion areas 66A and 66B may be areas not covered with silicide blocking film 70.

A transistor of example FIG. 3 may be a High Voltage (HV) Drain-Extended (DE) NMOS or PMOS. According to embodiments, if the transistor of example FIG. 3 is a DE-NMOS, well 60 may be P conductive type, and drift areas 64A and 64B and high concentration ion areas 66A and 66B may be N conductive type. According to embodiments, if the transistor of example FIG. 3 is a DE-PMOS, well 60 may be N conductive type, and drift areas 64A and 64B and high concentration ion areas 66A and 66B may be P conductive type.

A method for manufacturing a MOS transistor according to embodiments will be described with reference to example FIGS. 4A to 4D. Example FIGS. 4A to 4D are cross-sectional views illustrating a method for manufacturing a MOS transistor, according embodiments. Example FIGS. 4A-4D are cross-sectional views illustrating a method for manufacturing a MOS transistor of example FIG. 3, and example FIG. 4D is a cross-sectional view taken along line II-II′ of example FIG. 3.

Referring to example FIG. 4A, well 60 may be formed in a semiconductor substrate defined as a field area and active area 62. Shallow trench isolations (STI) 80A and 80B may be formed in the field area. Gate patterns 67 and 82 may be formed on and/or over active area 62. According to embodiments, a gate insulating layer, such as an oxide film and polysilicon, may be sequentially stacked on and/or over active area 62. A photo process and an etching process may be performed thereon, which may form the gate patterns in which gate insulating film 82 and gate 67 may be stacked.

As shown in example FIG. 4B, an ion implantation process using gate patterns 67 and 82 as an ion implantation mask may be performed and may form drift areas 64A and 64B in active area 62. According to embodiments, high concentration source and drain areas may be formed in active area 62 at both sides of gate 67 in a subsequent process. The source and drain areas may be covered with drift areas 64A and 64B. According to embodiments, spacers 84 may be formed on and/or over both side walls of gate patterns 67 and 82. High concentration ion areas 66A and 66B may be formed in drift areas 64A and 64B, spaced from gate 67 by a predetermined distance. To form high concentration ion areas 66A and 66B, an ion implantation mask exposing high concentration ion areas 66A and 66B may be formed on and/or over an upper portion of well 60 including gate 67. High concentration impurity ions may be implanted using the ion implantation mask, which may form high concentration ion areas 66A and 66B. After high concentration areas 66A and 66B may be formed, the ion implantation mask may be removed. Drift areas 64A and 64B and high concentration ion areas 66A and 66B may be formed, and may form junctions of the high voltage transistor.

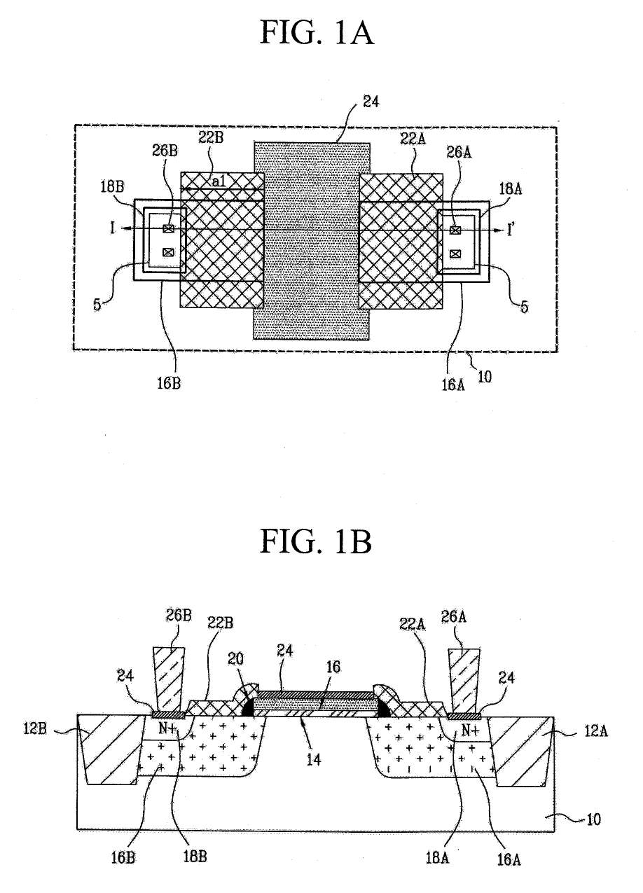

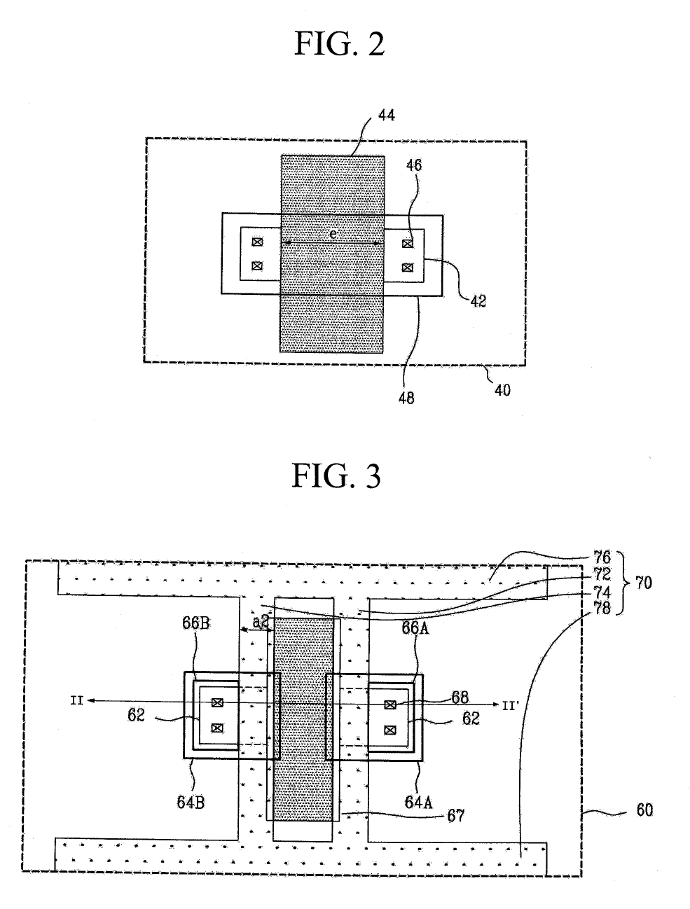

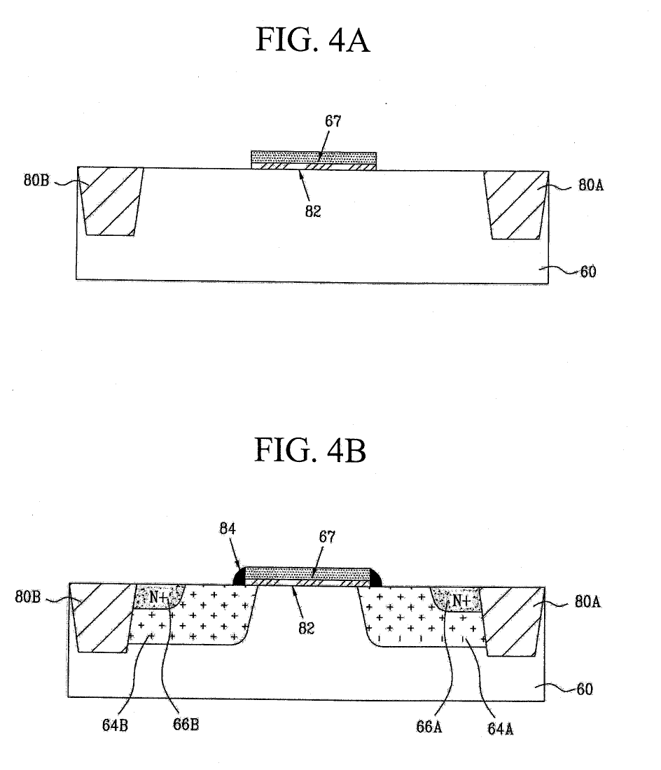

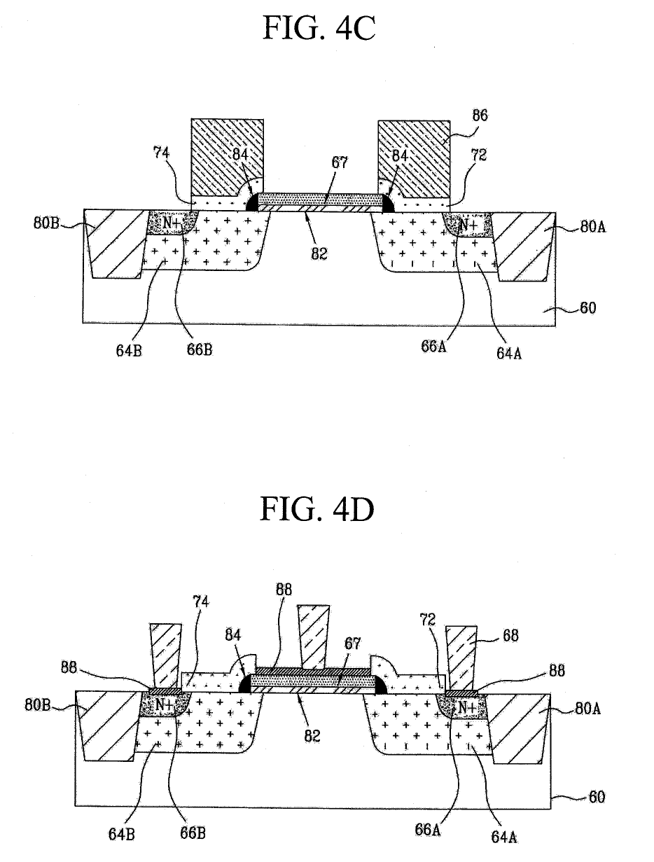

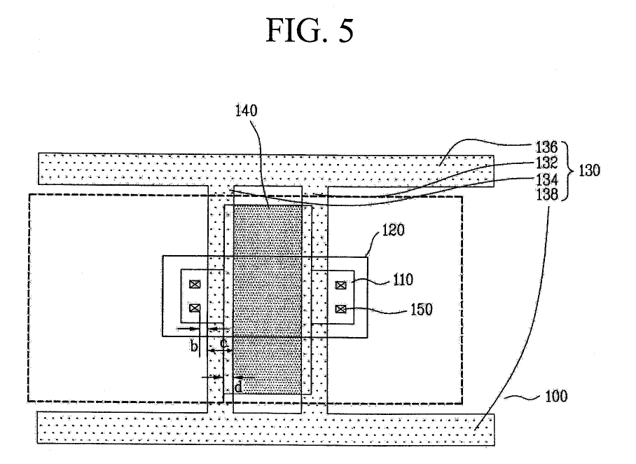

Referring to example FIG. 4C, silicide blocking film 70 may be formed on and/or over the entire uppermost surface of drift areas 64A and 64B and a portion of the uppermost surfaces of gate pattern 67 and high concentration ion areas 66A and 66B. From a top view, portions 72, 74 of silicide blocking film 70 vertically extend and may function to block silicide from forming between gate pattern 67 and high concentration ion areas 66A and 66B. According to embodiments, second portions 76, 78 of silicide blocking film 70, are spaced apart and extend perpendicularly with respect to horizontally-extending portions 72, 74, as shown in example FIG. 3 Portions 72, 74 are connected to second portions 76, 78 of silicide blocking film 70 on and/or over the field area. Portions 72, 74 and second portions 76, 78 may be connected to each other to prevent a collapse of pattern 86 that may occur if portions 72, 74 have a narrow width a2. A width a2 of silicide blocking film 70, as shown in example FIG. 3, may be smaller than width a1 of silicide blocking film 22A or 22B as shown in FIG. 1A.

According to embodiments, to form silicide blocking film 70, first silicide blocking material layer may be formed on and/or over upper portions of gate pattern 67, drift areas 64A and 64B, and high concentration ion areas 66A and 66B, as shown in example FIG. 4B. Photoresist patterns 86, which may expose space a2 between gate pattern 67 and high concentration ion areas 66A and 66B and areas on and/or over which parts 76 and 78 may be formed, may be formed on and/or over the silicon blocking material layer through photo process and etching process. The silicide blocking material layer may be etched using photoresist patterns 86. Silicide blocking film 70 may thus be formed as shown in example FIG. 3 or example FIG. 4C. If silicide blocking film 70 is completely formed, photoresist patterns 86 may be removed by ashing.

Referring to example FIG. 4D, silicide films 88 may be formed on and/or over gate pattern 67 and high concentration ion areas 66A and 66B, which may be areas not covered with silicide blocking film 70. As illustrated in example FIG. 4D, an interlayer insulating film may be stacked on and/or over the semiconductor substrate including silicide films 88. Via holes, which may expose silicide films 88, may be formed in the interlayer insulating films and then may be buried with metal such as tungsten. This may form contacts 68.

A MOS transistor according to embodiments will be described with reference to example FIG. 5. Example FIG. 5 illustrates a plan view of a MOS transistor according embodiments. Referring to example FIG. 5, well 100 may be formed in a semiconductor substrate defined as a field area and active area 110. Gate pattern 140 may be formed on and/or over active area 110. In a same manner as gate pattern 67 of example FIG. 3, gate pattern 140 may include a gate insulating film and a poly silicon gate. According to embodiments, high concentration ion area 120 may be formed on and/or over active area 110, differently from that as shown in example FIG. 3.

Silicide blocking films 130 may be formed on and/or over an upper portion of high concentration ion implantation area 120, between gate pattern 140 and contact areas 150. Parts 132 and 134 of silicide blocking film 130, which may be horizontally adjacent to each other on both sides of gate pattern 140, may vertically extend and may be connected to other parts 136 and 138 of silicide blocking film 130. In silicide blocking film 130, parts 132 and 134 may extend to an outside of well 100, which may be connected to other parts 136 and 138. A horizontal width of silicide blocking film 130 may be in proportion to a distance dcg from contact 150 formed in the contact area to an edge of gate pattern 140. According to embodiments, horizontal width c of silicide blocking film 130 may be determined as shown in following equation 1.

c=dcg−b+d Equation 1

According to embodiments, b may represent a distance between contact 150 and silicide blocking film 130, and d may represents an overlap width between silicide blocking film 130 and gate pattern 140, as shown in example FIG. 5. A distance b+c between contact 150 and gate 140 of a Middle Voltage (MV) transistor may be below 0.3 μm, so (0.3-b)+d may be obtained as an actual minimum Critical Dimension (CD) of the horizontal width of silicide blocking film 130 pattern. According to embodiments, distance b may be approximately 0.1 μm to 0.2 μm and width d may be approximately 0.1 μm to 0.3 μm. A CD of silicide blocking film 130 pattern may be determined approximately by a distance between contact 150 and gate 140. The silicide film may be formed on and/or over areas of the upper areas of gate pattern 140 and contact areas 150, which may be areas not covered with silicide blocking film 130. A transistor of example FIG. 5 may be a Middle Voltage (MV) Drain-Extended (DE) NMOS or PMOS transistor. If the transistor is a MV DE-NMOS transistor, high concentration doped area 120 may be N conductive type. According to embodiments, if the transistor is a MV DE-PMOS transistor, high concentration doped area 120 may be P conductive type.

A method for manufacturing a MOS transistor of example FIG. 5 according to embodiments will be described. According to embodiments, well 100 may be formed in a semiconductor substrate defined as a field area and active area 110. Gate pattern 140 may be formed on and/or over active area 110. A gate insulating layer and a poly silicon layer may be sequentially stacked on and/or over an upper portion of active area 110 and a photo process and an etching process may be performed thereon. This may form gate pattern 140. As shown in example FIG. 5, high concentration ion area 120 may be formed on and/or over active area 110. In a transistor of example FIG. 3, high concentration ion areas 66A and 66B may be formed in drift areas 64A and 64B, spaced from gate pattern 67. In the transistor of example FIG. 5, high concentration ion area 120 may be formed by implanting high concentration impurity ions into active area 110.

According to embodiments, silicide blocking film 130 may be formed on and/or over an upper portion of high concentration ion implantation area 120, between gate pattern 140 and contact 150. Parts 132 and 134 of silicide blocking film 130 horizontally adjacent to each other having gate pattern 140 therebetween may vertically extend to be connected to other parts 136 and 138. Silicide blocking films 132 and 134 may extend to outside of well 100, and may be connected to silicide blocking films 136 and 138 outside well 100. A detailed process for forming silicide blocking film 130 may be substantially the same as that for forming silicide blocking film 70 of example FIG. 3. A silicide film may be formed on and/or over upper areas of gate pattern 140 and contact areas, which may be areas not covered with silicide blocking film 130. A method for forming a contact and source and drain areas, and the like may be substantially the same as that for manufacturing a transistor of example FIG. 3.

In other methods, each silicide blocking film for a high voltage transistor may have an independent bar shape (rectangular cross-section) and may be formed independently on and/or over drift areas at both sides of a gate pattern. According to embodiments, however, in a MOS transistor and a method for manufacturing the transistor, silicide blocking films may be connected to each other in a field area and the bar shapes may be supported by each other. This may make it possible to prevent a collapsed pattern issue due to insufficient surface in contact with a sub-material and a high aspect ratio (the ratio of vertical size to horizontal size) and may reduce minimum Critical Dimension (CD) of the silicide blocking film more efficiently as compared to the related art.

According to embodiments, a pattern of the silicide blocking film may be minimized and an overlap between the gate pattern and the silicide blocking films may be minimized. This may make it possible to lower a resistance of a gate pattern as compared to the related art and secure more even gate resistors. According to embodiments, a dispersion of resistors of the matching property may be improved. The increase of breakdown voltage between drain and source of the high voltage transistor and the reduction of the gate length of the transistor may thereby be accomplished.

In a middle voltage (MD) transistor in a related art device, a silicide blocking film may not be formed. According to embodiments, however, a silicide blocking film may be formed on and/or over an area between a gate pattern and contacts, that is, upper portions of high concentration source and drain areas. This may increase a breakdown voltage between the drain and source and may reduce the gate length of the transistor. It may also prevent a collapsed pattern issue and secure a photo margin by connecting the patterns of the silicide blocking film, which may support each other. A high voltage transistor and middle voltage transistor may have a reduced pitch size. This may make it possible to improve certain properties of the transistor, such as reduction in entire chip size.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
providing a semiconductor substrate having an active area and a field area; and then
forming a gate pattern over the active area of the semiconductor substrate; and then
forming silicide blocking films at each side of the gate pattern and partially over the uppermost surface of the gate pattern,
wherein the silicide blocking films include first and second silicide blocking film portions formed spaced apart and extending in parallel to each other, and third and fourth silicide blocking film portions connected to the first and second silicide blocking film portions and formed spaced apart and extending in parallel to each other and perpendicular to the first and second silicide blocking film portions.

2. The method of claim 1, further comprising:
forming drift areas in the active area using the gate pattern as an ion implantation mask;
forming high concentration ion areas in the drift areas, spaced apart from the gate pattern; and then
forming silicide films over the gate pattern and the high concentration ion area, being areas not covered with the silicide blocking film,
wherein the silicide blocking films are formed over the drift areas, between the gate pattern and the high concentration ion areas.

3. The method of claim 2, wherein the silicide blocking films are connected to each other over the field area.

4. The method of claim 2, further comprising forming a High Voltage (HV) Derain-Extended (DE) MOS transistor.

5. The method of claim 1, further comprising:
forming high concentration ion areas over the active area; and then
forming silicide films over the gate pattern and contact areas, being areas not covered with the silicide blocking film,
wherein the silicide blocking films are formed over the high concentration ion implantation areas, between the gate pattern and the contact areas.

6. The method of claim 5, wherein a width of the silicide blocking films is determined according to a distance from contacts formed in the contact areas to the gate pattern.

7. The method of claim 5, further comprising forming a contact over each high concentration ion area, wherein a distance between each contact and an outside edge of the silicide blocking films is approximately 0.1 μm to 0.2 μm.

8. The method of claim 5, wherein a width of an overlap of the gate pattern and the silicide blocking films is approximately 0.1 μm to 0.3 μm.

9. The method of claim 5, further comprising forming a Middle Voltage (MV) Derain-Extended (DE) MOS transistor.

10. The method of claim 5, further comprising forming a well in the semiconductor substrate, wherein the silicide blocking films extend to an outside portion of the well to be connected to each other.

11. A device comprising:
a semiconductor substrate including an active area and a field area;
a gate pattern formed over the active area of the semiconductor substrate; and
silicide blocking films at each side of the gate pattern and partially over the uppermost surface of the gate pattern,
wherein the silicide blocking films include first and second silicide blocking film portions formed spaced apart and extending in parallel to each other, and third and fourth silicide blocking film portions connected to the first and second silicide blocking film portions and formed spaced apart and extending in parallel to each other and perpendicular to the first and second silicide blocking film portions.

12. The device of claim 11, further comprising:
drift areas formed to surround source and drain areas at both sides of the gate pattern;
high concentration ion areas formed in the drift areas, spaced apart from the gate pattern; and
silicide films formed over the gate pattern and the high concentration ion area, being areas not covered with the silicide blocking film,
wherein the silicide blocking films are formed over the drift areas, and positioned between the gate pattern and the high concentration ion areas.

13. The device of claim 12, wherein the silicide blocking films are connected to each other over the field area.

14. The device of claim 12, further comprising a High Voltage (HV) Derain-Extended (DE) MOS transistor.

15. The device of claim 11, further comprising:
high concentration ion areas formed over the active area;
silicide films formed over the gate pattern and contact areas, the gate pattern and the contact areas being areas not covered with the silicide blocking film,
wherein the silicide blocking films are formed over the high concentration ion implantation areas, and positioned between the gate pattern and the contact areas.

16. The device of claim 15, wherein a horizontal width of the silicide blocking film is in proportion to a distance from contacts formed over the contact area to the gate pattern.

17. The device of claim 15, further comprising a contact formed over each high concentration ion area, wherein a distance between each contact and an outside edge of the silicide blocking films is in a range between approximately 0.1 μm to 0.2 μm.

18. The device of claim 15, wherein a width of an overlap of the gate pattern and the silicide blocking films is in a range between approximately 0.1 μm to 0.3 μm.

19. The device of claim 15, further comprising a well formed in the semiconductor substrate, wherein the silicide blocking films extend to an outside of the well to be connected to each other.

20. The device of claim 15, further comprising a Middle Voltage (MV) Derain-Extended (DE) MOS transistor.
